(19) United States
(12) Patent Application Publication
(10) Pub. No.: US 2013/0256684 A1
(43) Pub. Date: Oct. 3, 2013

(54) COMPOUND SEMICONDUCTOR DEVICE AND METHOD OF MANUFACTURING THE SAME

(71) Applicant: FUJITSU LIMITED, Kawasaki-shi (JP)

(72) Inventors: Masato NISHIMORI, Atsugi (JP); Toshihide Kikkawa, Machida (JP); Tadahiro Imada, Kawasaki (JP)

(21) Appl. No.: 13/724,903

(22) Filed: Dec. 21, 2012

(30) Foreign Application Priority Data
Mar. 28, 2012 (JP) 2012-074962

(51) Int. Cl. H01L 29/778; H01L 29/66

(52) U.S. Cl. CPC H01L 29/7783; H01L 29/66431
USPC 257/76; 257/194; 438/172

(57) ABSTRACT

An embodiment of a compound semiconductor device includes: a substrate; an electron transport layer formed over the substrate; an electron supply layer formed over the electron transport layer; a source electrode and a drain electrode formed over the electron supply layer; a gate electrode formed over the electron supply layer between the source electrode and the drain electrode; a p-type compound semiconductor layer formed between the electron supply layer and the gate electrode; and a compound semiconductor layer containing an n-type impurity formed between the electron supply layer and the p-type compound semiconductor layer.

### CROSS-REFERENCE TO RELATED APPLICATION

This application is based upon and claims the benefit of priority of the prior Japanese Patent Application No. 2012-074962, filed on Mar. 28, 2012, the entire contents of which are incorporated herein by reference.

### FIELD

The embodiments discussed herein are related to a compound semiconductor device and a method of manufacturing the same.

### BACKGROUND

A hetero junction between an AlGaN layer and a GaN layer is used and the GaN layer functions as an electron transport layer in a GaN-based high electron mobility transistor (HEMT). GaN has a wide band gap, a high breakdown voltage and a high electron mobility. Therefore, GaN is extremely promising as a material for large current operation, high voltage operation and low on-resistance operation. There have been investigations about adopting the GaN-based HEMT to a future effective transistor for a base station or the like, a high effective switching element for controlling electric power, and so on. In the GaN-based HEMT, a distortion is produced in the AlGaN layer due to a lattice mismatch between AlGaN and GaN, the distortion triggers a piezo polarization, and a high density two-dimensional electron gas is generated in the vicinity of the upper surface of the GaN layer beneath the AlGaN layer. Thus, a high output may be obtained.

However, it is difficult to obtain normally-off transistors due to high density of the two-dimensional electron gas. Investigations into various techniques have therefore been directed to solve the problem. Conventional proposals include a technique of disconnecting the two-dimensional electron gas by etching a portion of the electron supply layer just below the gate electrode, and a technique of vanishing the two-dimensional electron gas by forming a p-type GaN layer between the gate electrode and the electron supply layer.

Etching of the portion of the electron supply layer just below the gate electrode will, however, damage the electron transport layer, to thereby induce problems of increase in sheet resistance and increase in leakage current. Formation of the p-type GaN layer will elevate resistivity and deteriorate maximum current. In this way, conventional efforts to obtain the normally-off transistors have degraded other characteristics of the transistors.
[Patent Literature 1] Japanese Laid-Open Patent Publication No. 2009-076845
[Patent Literature 2] Japanese Laid-Open Patent Publication No. 2007-019309
[Patent Literature 3] Japanese Laid-Open Patent Publication No. 2007-201279
[Patent Literature 4] International Publication Pamphlet No. WO2007108055

### SUMMARY

According to an aspect of the embodiments, a compound semiconductor device includes: a substrate; an electron transport layer formed over the substrate; an electron supply layer formed over the electron transport layer; a source electrode and a drain electrode formed over the electron supply layer; a gate electrode formed over the electron supply layer between the source electrode and the drain electrode; a p-type compound semiconductor layer formed between the electron supply layer and the gate electrode; and a compound semiconductor layer containing an n-type impurity formed between the electron supply layer and the p-type compound semiconductor layer.

According to another aspect of the embodiments, a method of manufacturing a compound semiconductor device includes: forming an electron transport layer over a substrate; forming an electron supply layer over the electron transport layer; forming a compound semiconductor layer containing an n-type impurity over the electron supply layer; forming a p-type compound semiconductor layer over the compound semiconductor layer containing an n-type impurity; etching the p-type compound semiconductor layer so as to remain a part of the p-type compound semiconductor layer; annealing so as to activate a p-type impurity in the p-type compound semiconductor layer; forming a source electrode and a drain electrode over the electron supply layer so that the remaining part of the p-type compound semiconductor layer is between the source electrode and the drain electrode; and forming a gate electrode over the remaining part of the p-type compound semiconductor layer.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a cross sectional view illustrating a structure of a compound semiconductor device according to a first embodiment;

FIGS. 2A to 2K are cross sectional views illustrating, in sequence, a method of manufacturing a compound semiconductor device according to the first embodiment;

FIG. 3 is a cross sectional view illustrating a modification example of the first embodiment;

FIGS. 4A and 4B are cross sectional views illustrating other modification examples of the first embodiment;

FIGS. 5A to 5C are cross sectional views illustrating, in sequence, a method of manufacturing a compound semiconductor device according to a referential example;

FIG. 6 is a diagram illustrating a relation between a drain voltage and a drain current;

FIG. 7 is a cross sectional view illustrating a structure of a compound semiconductor device according to a second embodiment;

FIGS. 8A to 8H are cross sectional views illustrating, in sequence, a method of manufacturing a compound semiconductor device according to the second embodiment;

FIG. 9 is a cross sectional view illustrating a modification example of the second embodiment;

FIGS. 10A and 10B are cross sectional views illustrating other modification examples of the second embodiment;

FIG. 11 is a drawing illustrating a discrete package according to a third embodiment;

FIG. 12 is a wiring diagram illustrating a power factor correction (PFC) circuit according to a fourth embodiment;

FIG. 13 is a wiring diagram illustrating a power supply apparatus according to a fifth embodiment; and

FIG. 14 is a wiring diagram illustrating a high-frequency amplifier according to a sixth embodiment.

### DESCRIPTION OF EMBODIMENTS

The present inventors extensively investigated into the reasons why the resistivity is elevated and the maximum current is deteriorated, when the p-type GaN layer is formed, in prior arts. Then, it was found out that it is extremely difficult to control etching for providing the p-type GaN layer in a pre-determined position. In the prior art, the p-type GaN layer is etched after it is formed over the electron transport layer. If the etching is excessive (over-etching), the electron transport layer is thinned too much, the two-dimensional electron gas decrease, and then, the resistivity is elevated and the maximum current is deteriorated. If the etching is short (under-etching), the p-type GaN layer remained excessively over the electron transport layer, the two-dimensional electron gas vanishes, and then, the resistivity is elevated and the maximum current is deteriorated. Moreover, a leakage current sometimes flows through the excessively remaining p-type GaN layer. In this way, it is difficult to control etching the p-type GaN layer, and that makes it difficult to obtain desired characteristics in the prior arts. An AlGaN layer with a high Al fraction may be formed before forming the p-type GaN layer in order to control the etching, but the AlGaN layer, which remains even after etching the p-type GaN layer, is likely to be oxidized, and other problems such as a current collapse arise. The present inventors have conceived, based on these findings and knowledge, an idea that an n-type GaN layer is formed before forming a p-type GaN layer.

Embodiments will be detailed below, referring to the attached drawings.

### First Embodiment

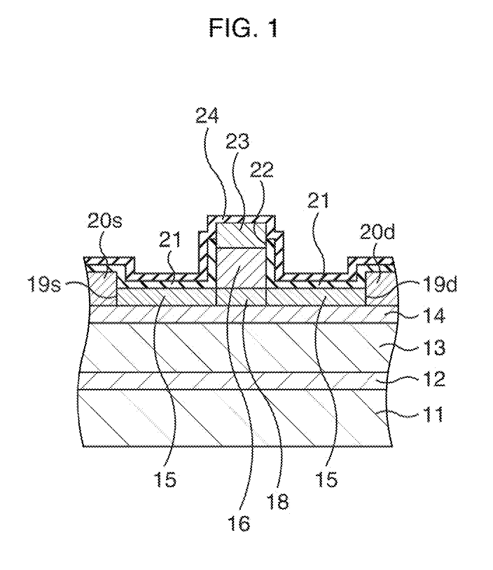

First, a first embodiment will be described. FIG. 1 is a cross sectional view illustrating a structure of a GaN-based HEMI (compound semiconductor device) according to the first embodiment.

In the first embodiment, a buffer layer (nucleation layer) 12 is formed over a substrate, as illustrated in FIG. 1. For example, the substrate 11 may be a Si substrate, and the buffer layer 12 may be an AlN layer. An electron transport layer 13 is formed over the buffer layer 12. The electron transport layer 13 may be an undoped i-GaN layer, for example, whose thickness is approximately 1 μm to 4 μm, for example 3 μm or around. An electron supply layer 14 is formed over the electron transport layer 13. The electron supply layer 14 may be an undoped i-AlGaN layer, for example, whose thickness is approximately 1 nm to 30 nm, for example 20 nm or around. The Al fraction of the electron supply layer 14 may be approximately 0.1 to 0.5, for example 0.2 or around. Thus, each of the electron transport layer 13 and the electron supply layer 14 contains a GaN-based material. An n-type compound semiconductor layer 15 containing an n-type impurity is formed over the electron supply layer 14. The n-type compound semiconductor layer 15 may be an n-type n-GaN layer, for example, whose thickness is approximately 10 nm to 30 nm, for example 20 nm or around. Si may be doped to the n-type compound semiconductor layer 15 at approximately 1×10¹⁷ cm⁻³ to 1×10¹⁹ cm⁻³, for example 2×10¹⁸ cm⁻³ or around. When Si is doped at approximately 1×10¹⁷ cm⁻³ or higher, an after-mentioned effect for suppressing a current collapse is dominant. When Si is doped at higher than approximately 1×10¹⁹ cm⁻³, a leakage current sometimes flows too much.

An element isolation region which defines an element region is formed in a compound semiconductor stacked structure including the buffer layer 12, the electron transport layer 13, the electron supply layer 14 and the n-type compound semiconductor layer 15. An recess 19s and an recess 19d are formed in the n-type compound semiconductor layer 15 in the element region. A source electrode 20s is formed in the recess 19s, and a drain electrode 20d is formed in the recess 19d. A p-type region 18 is provided at a part in the n-type compound semiconductor layer 15, the part being between the source electrode 20s and the drain electrode 20d in planar view. A p-type compound semiconductor layer 16 is formed over the p-type region 18. The p-type compound semiconductor layer 16 may be a p-type p-GaN layer, for example, whose thickness is approximately 30 nm to 100 nm, for example 80 nm or around. Mg may be doped as a p-type impurity to the p-GaN layer at approximately 5×10¹⁹ cm⁻³, for example. The p-type region 18 may be formed, for example, through diffusion of the p-type impurity from the p-type compound semiconductor layer 16 to the n-type compound semiconductor layer 15, although the details will be described later. Therefore, the p-type region 18 contains not only the p-type impurity but also the n-type impurity.

A passivation film 21 is formed over the n-type compound semiconductor layer 15 so as to cover the source electrode 20s and the drain electrode 20d. an opening 22 is formed in the passivation film 21 so as to expose the p-type compound semiconductor layer 16, and a gate electrode 23 is formed in the opening 22. A passivation film 24 is formed over the passivation film 21 so as to cover the gate electrode 23. Materials of the passivation films 21 and 24 are not limited to particular ones, and an insulating film such as a Si nitride film may be used for each of the passivation films 21 and 24.

In the first embodiment, the normally-off operation can be achieved, since the p-type compound semiconductor layer 16 is provided between the gate electrode 23 and the electron supply layer 14. Thinning the electron supply layer 14 is avoidable even if sufficient etching is performed for forming the p-type compound semiconductor layer 16, since the n-type compound semiconductor layer 15 exists over the electron supply layer 14, although the details will be described later. The n-type compound semiconductor layer 15 may diminish the two dimensional electron gas (2DEG) in the vicinity of the interface of the electron transport layer 13 to the electron supply layer 14 compared to a case where the n-type compound semiconductor layer 15 is not provided, but the amount is marginal. Therefore, the resistance is sufficiently low and the sufficient maximum current can be obtained, even though the n-type compound semiconductor layer 15 is provided. Moreover, the p-type region 18 and the n-type compound semiconductor layer 15 are adjacent to each other, and thus, pn-junctions exist between them. The pn-junctions exist at the source electrode 20s side and the drain electrode 20d side of the p-type region 18, and one at the drain electrode 20d side especially contributes to improvement of the breakdown voltage. Besides, when the n-type compound semiconductor layer 15 does not contain Al, the n-type compound semiconductor layer 15 is not likely to be oxidized and increase of the current collapse due to oxidization can be suppressed.

The recesses 19s and 19d does not always have to be formed, and the n-type compound semiconductor layer 15 may exist between the electron supply layer 14 and the source electrode 20s, the drain electrode 20d. Incidentally, the contact resistance is lower and more desired characteristics may be obtained in the case where the source electrode 20s and the drain electrode 20d are in direct contact with the electron supply layer 14.

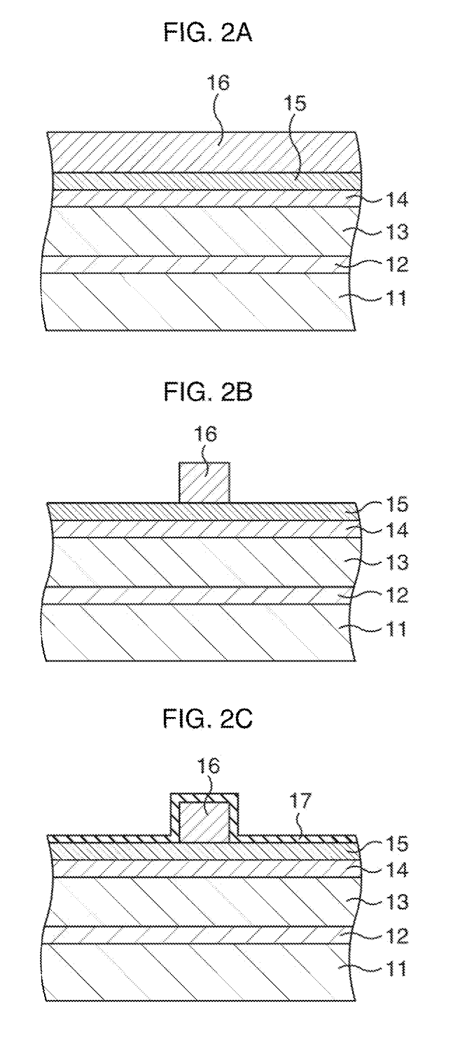

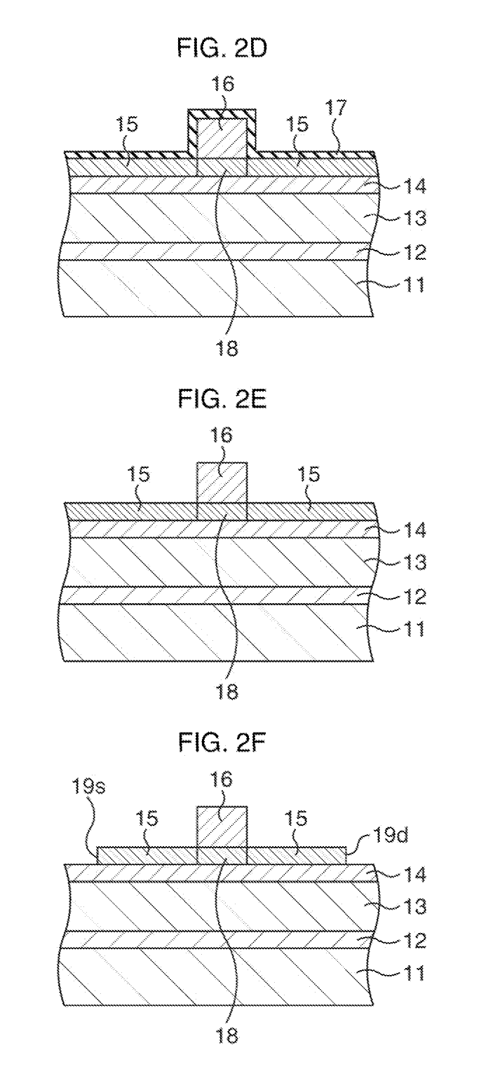

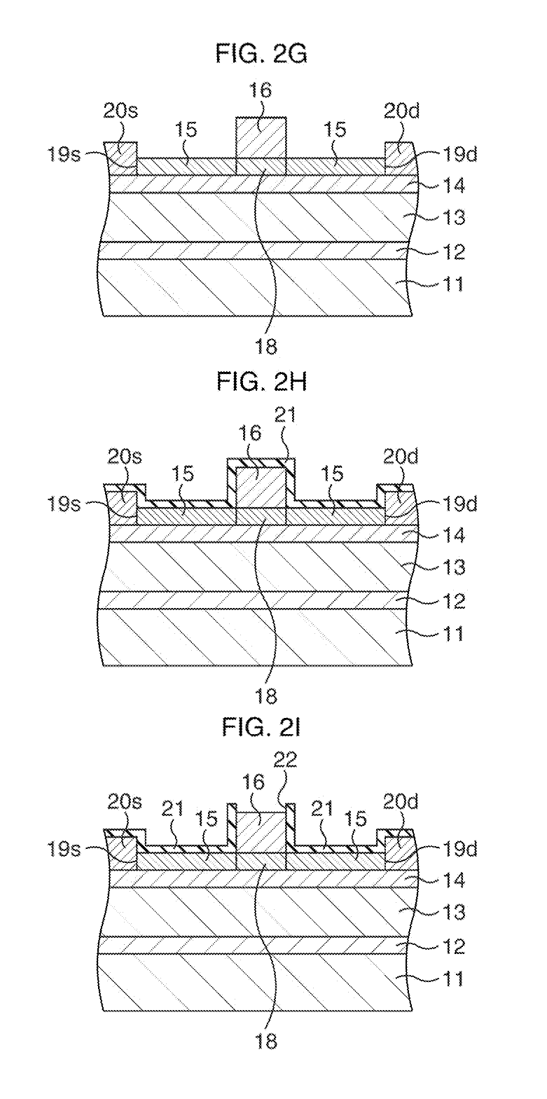

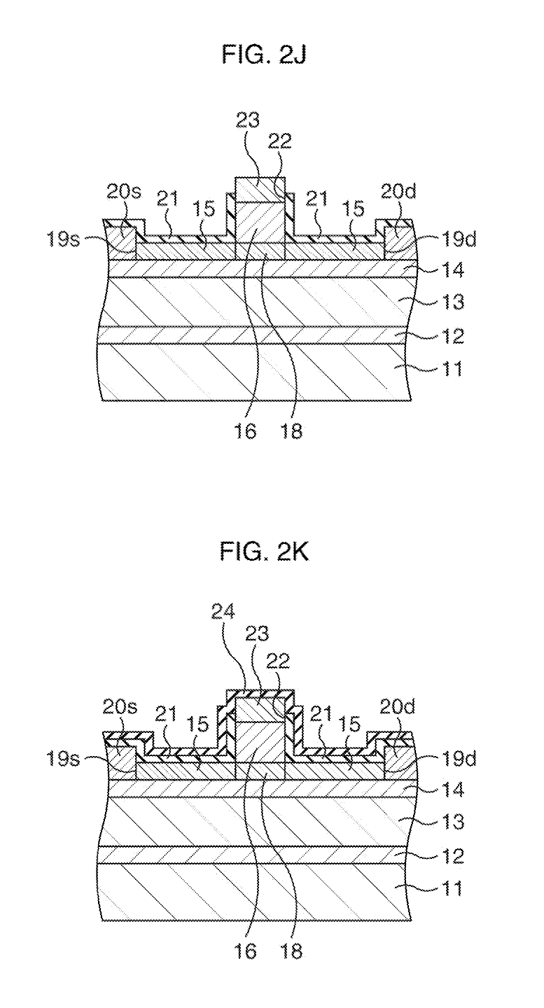

Next, a method of manufacturing the GaN-based HEMT (compound semiconductor device) according to the first embodiment will be explained. FIG. 2A to FIG. 2K are cross sectional views illustrating, in sequence, the method of manufacturing the GaN-based HEMT (compound semiconductor device) according to the first embodiment.

First, the buffer layer 12, the electron transport layer 13, the electron supply layer 14, the n-type compound semiconductor layer 15 and the p-type compound semiconductor layer 16 are formed over the substrate 11, as illustrated in FIG. 2A. The buffer layer 12, the electron transport layer 13, the electron supply layer 14, the n-type compound semiconductor layer 15 and the p-type compound semiconductor layer 16 may be formed by a crystal growth method such as an MOVPE (metal organic vapor phase epitaxy), for example. In this case, these layers may be continuously formed by selecting source gases. Trimethylaluminum (TMA1) gas and trimethylgallium (TMG) gas may be used, for example, for sources for aluminum (Al) and gallium (Ga), respectively. Ammonia (NH₃) gas may be used, for example, for a source for nitrogen (N). Silane (SiH₄) may be used, for example, for a source for silicon (Si) contained as an impurity in an n-GaN layer. Cyclopentadienyl magnesium (CpMg) may be used, for example, for a source for magnesium (Mg) contained as an impurity in a p-GaN layer. These GaN-based compound semiconductor layers may be formed, for example, in reduced pressure atmosphere with the substrate 11 being heated.

Then, the element isolation region which defines the element region is formed in a compound semiconductor stacked structure including the buffer layer 12, the electron transport layer 13, the electron supply layer 14, the n-type compound semiconductor layer 15 and the p-type compound semiconductor layer 16. In forming the element isolation region, for example, a photoresist pattern is formed over the p-type compound semiconductor layer 16 so as to selectively expose a region where the element isolation region is to be formed, and ion such as Ar ion is implanted through the photoresist pattern used as a mask. Alternatively, the compound semiconductor stacked structure may be etched by dry etching using a chlorine-containing gas with the photoresist pattern used as an etching mask.

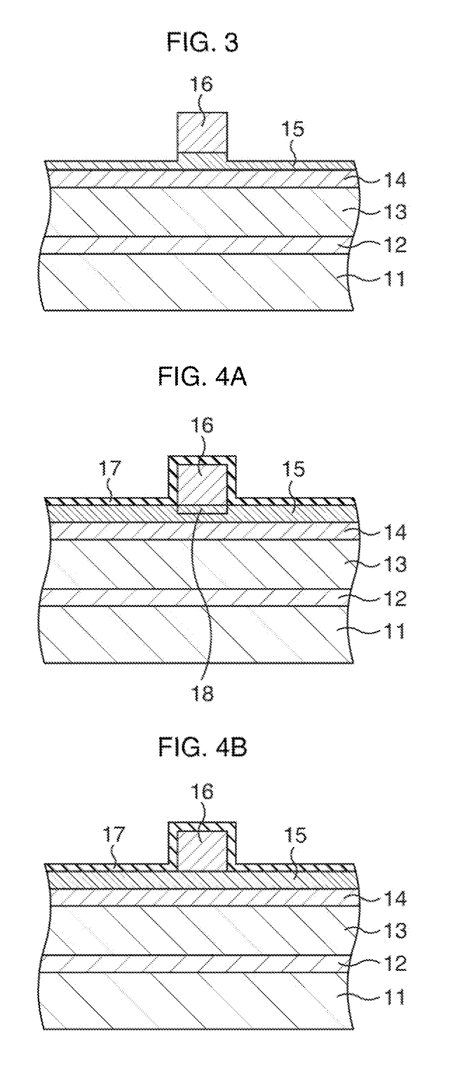

Thereafter, a resist pattern is formed over the p-type compound semiconductor layer 16 so as to selectively cover a region where the p-type compound semiconductor layer 16 is to remain and expose the other region. The p-type compound semiconductor layer 16 is dry-etched with the resist pattern used as a mask, as illustrated in FIG. 2B. A chlorine-containing gas, for example, may be used for an etching gas in the dry etching. The dry etching is controlled so as to end at a point in the n-type compound semiconductor layer 15 in order to certainly remove the part of the p-type compound semiconductor layer 16 exposed from the resist pattern. The dry etching is also controlled so as to remain the n-type compound semiconductor layer 15 even at a region where the etching amount is the highest in consideration of variation of the etching rate in plane. The controls may be easily conducted when the thickness of the n-type compound semiconductor layer 15 is approximately 10 nm to 30 nm, for example 20 nm or around. Half of the n-type compound semiconductor layer 15, for example, may be etched in the thickness direction, as illustrated in FIG. 3.

Subsequently, a protective film 17 is formed over the n-type compound semiconductor layer 15 so as to cover the p-type compound semiconductor layer 16, as illustrated in FIG. 2C. A silicon nitride film may be formed for the protective film 17, for example.

Then, annealing is performed so as to activate the p-type impurity, for example Mg, in the p-type compound semiconductor layer 16. Moreover, the p-type impurity in the p-type compound semiconductor layer 16 diffuses into the n-type compound semiconductor layer 15 during the annealing, and the p-type region 18 is formed, as illustrated in FIG. 2D.

Thereafter, the protective film 17 is removed, as illustrated in FIG. 2E. The protective film 17 may be removed with hydrofluoric acid, for example.

Subsequently, the recess 19s and the recess 19d are formed in the n-type compound semiconductor layer 15 in the element region, as illustrated in FIG. 2F. In forming the recess 19s and the recess 19d, for example, a resist pattern is formed over the n-type compound semiconductor layer 15 and the p-type compound semiconductor layer 16 so as to selectively expose the regions where the recess 19s and the recess 19d are to be formed and cover the other region, and then, dry etching is performed with a chlorine-containing gas using the resist pattern as a mask.

Then, the source electrode 20s is formed in the recess 19s, and the drain electrode 20d is formed in the recess 19d, as illustrated in FIG. 2G. The source electrode 20s and the drain electrode 20d may be formed by a lift-off process, for example. More specifically, a resist pattern is formed so as to expose regions where the source electrode 20s and the drain electrode 20d are to be formed, vapor depositions of Ta and Al are performed using the resist pattern as a growth mask in a reduced pressure atmosphere, and the resist pattern is then removed together with the portion of Ta and Al deposited thereon. Then, annealing is performed, for example, in a nitrogen atmosphere at approximately 400° C. to 1000° C., for example 600° C. or around, so as to ensure ohmic characteristic of the source electrode 20s and the drain electrode 20d.

Thereafter, the passivation film 21 is formed over the entire surface, as illustrated in FIG. 2H. The passivation film 21 is preferably formed, for example, by atomic layer deposition (ALD), plasma-assisted (chemical vapor deposition) CVD or sputtering.

Subsequently, the opening 22 exposing the p-type compound semiconductor layer 16 is formed in a portion of the passivation film 21 above the p-type compound semiconductor layer 16, as illustrated in FIG. 2I. The opening 22 may be formed, for example, by dry etching with a tetrafluoromethane (CF₄) gas.

Then, the gate electrode 23 is formed in the opening 22, as illustrated in FIG. 2J. The gate electrode 23 may be formed by a lift-off process, for example. More specifically, a resist pattern is formed so as to expose a region where the gate electrode 23 is to be formed, vapor depositions of Pt and Au are performed using the resist pattern as a growth mask in a reduced pressure atmosphere, and the resist pattern is then removed together with the portion of Pt and Au deposited thereon.

Thereafter, the passivation film 24 is formed over the passivation film 21 so as to cover the gate electrode 23, as illustrated in FIG. 2K.

The GaN-based HEMT according to the first embodiment may be thus manufactured.

The n-type compound semiconductor layer 15 is formed between the electron supply layer 14 and the p-type compound semiconductor layer 16 in the manufacturing method, and therefore, the p-type compound semiconductor layer 16 may be etched sufficiently with avoiding the electron supply layer 14 being thinned. Accordingly, the increase of resistance and the decrease of maximum current can be suppressed, while the normally-off operation can be achieved.

Incidentally, the p-type impurity diffuses in not only the thickness direction but also the lateral direction of the n-type compound semiconductor layer 15, and the p-type region may be formed so as to extend toward to the source electrode 20s and the drain electrode side 20d. However, the diffusion distance is equivalent to the thickness of the n-type compound semiconductor layer 15 at a maximum, and therefore, it is marginal compared to the distance between the gate electrode 23 and the source electrode 20s (2 μm, for example) and the distance between the gate electrode 23 and the drain electrode 20d (10 μm to 15 μm, for example). Moreover, in some cases, the n-type compound semiconductor layer 15 may remain beneath the p-type region 18, as illustrated in FIG. 4A, and the p-type region 18 may be rarely formed, as illustrated in FIG. 4B, depending on conditions of the activating annealing. Conditions of the activating annealing are not limited to particular ones, and it is preferable that the annealing is performed so as for the p-type impurity in the p-type compound semiconductor layer 16 not to diffuse up to the electron supply layer 14, in short, for the diffusion to stop in the n-type compound semiconductor layer 15.

A p-AlGaN layer may be used for the p-type compound semiconductor layer 16 instead of the p-GaN layer. The p-GaN layer has a merit in which the normally-off operation is likely to be achieved, and the p-AlGaN layer has a merit in which the layer is easy to grow, when the p-AlGaN layer and the p-GaN are compared. Thus, the p-type compound semiconductor layer 16 may be an AlₓGa₁₋ₓN layer (0≦x<1).

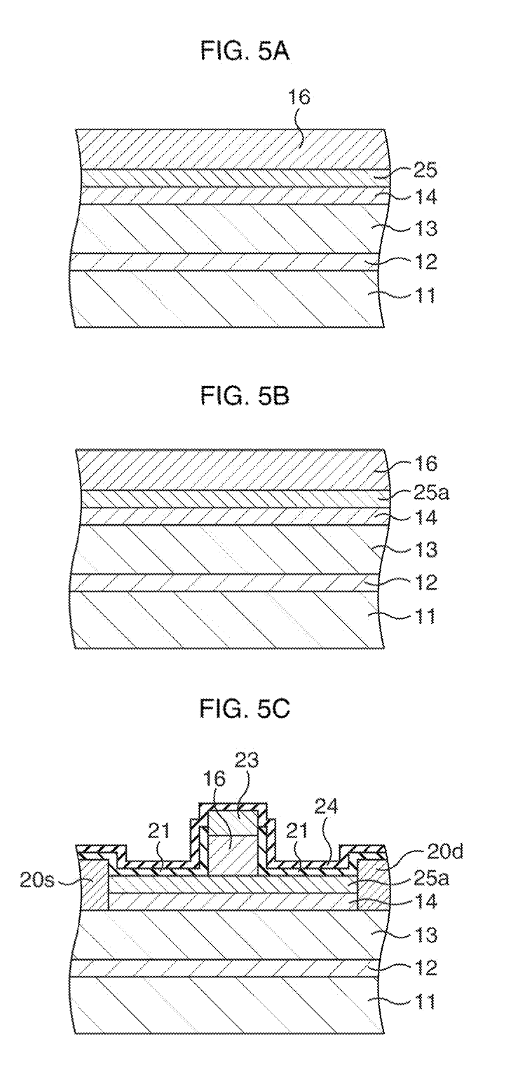

Characteristics of the first embodiment will be described with comparing to a referential example. FIGS. 5A to 5C are cross sectional views illustrating, in sequence, a method of manufacturing a compound semiconductor device according to the referential example. For manufacturing the referential example, first, the buffer layer 12, the electron transport layer 13 and the electron supply layer 14 are formed over the substrate, as illustrated in FIG. 5A, similarly to the first embodiment. Then, an undoped i-GaN layer 25 is formed instead of the n-type compound semiconductor layer 15 over the electron supply layer 14, and the p-type compound semiconductor layer 16 is formed over the i-GaN layer 25. Then, annealing is performed so as to activate the p-type impurity in the p-type compound semiconductor layer 16. The p-type impurity in the p-type compound semiconductor layer 16 diffuses into the i-GaN layer 25 during the annealing, and the i-GaN layer 25 turns into a GaN layer 25a containing p-type impurity, as illustrated in FIG. 5B. Thereafter, the etching of the p-type compound semiconductor layer 16 and the processes thereafter are performed similarly to the first embodiment, as illustrated in FIG. 5C.

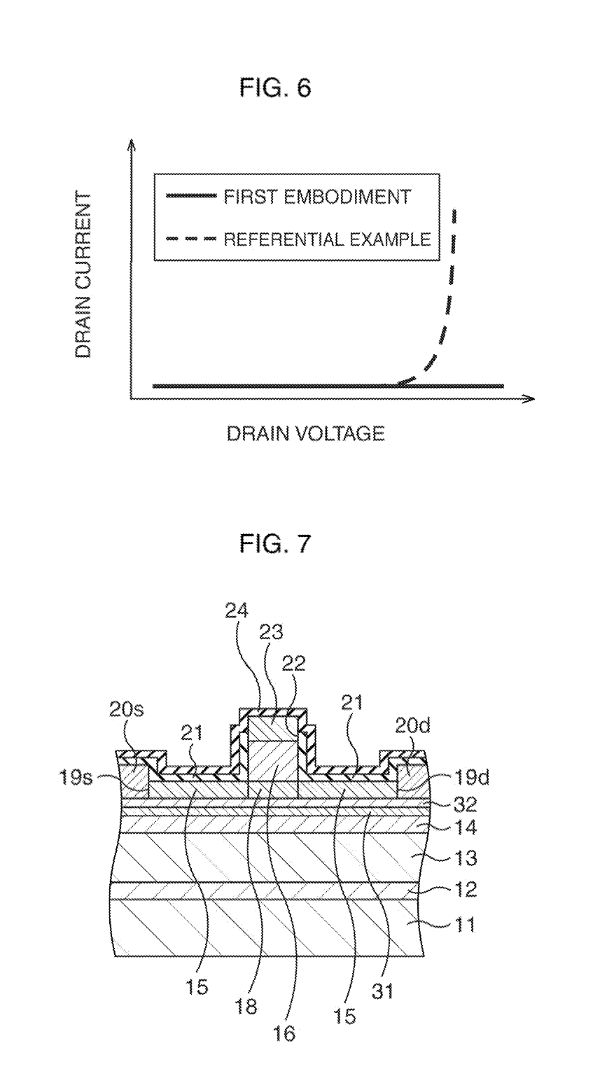

When breakdown voltages of the referential example and the first embodiment are measured, results illustrated in FIG. 6 are obtained. In other words, a high breakdown voltage can be obtained in the first embodiment due to the pn-junction between the p-type region 18 and the n-type compound semiconductor layer 15, although a breakdown voltage of the referential example is poorer than the first embodiment due to lack of the pn-junction.

### Second Embodiment

Next, a second embodiment will be described. FIG. 7 is a cross sectional view illustrating a structure of a GaN-based HEMT (compound semiconductor device) according to the second embodiment.

In the second embodiment, an n-type compound semiconductor layer 31 and an AlN layer 32 are formed over the electron supply layer 14, as illustrated in FIG. 7. The n-type compound semiconductor layer 31 may be an n-type n-GaN layer, for example, whose thickness is approximately 2 nm to 10 nm, for example 5 nm or around. Si may be doped to the n-type compound semiconductor layer 31 at approximately 1×10¹⁷ cm⁻³ to 1×10¹⁹ cm⁻³, for example 2×10¹⁸ cm⁻³ or around. The thickness of the AlN layer 32 is approximately 0.5 nm to 3 nm, for example 2 nm or around. The n-type compound semiconductor layer 15, the p-type region 18, the source electrode 20s, the drain electrode 20 and so on are formed over the AlN layer 32 similarly to the first embodiment. The other structure is the same as the first embodiment. Incidentally, the critical thickness is 3 nm or around when an AlN layer grows on a GaN layer.

In the second embodiment, along with the same effect as the first embodiment, the sheet resistance can be reduced much more and the current collapse can be suppressed much more due to a so-called three-cap-structure.

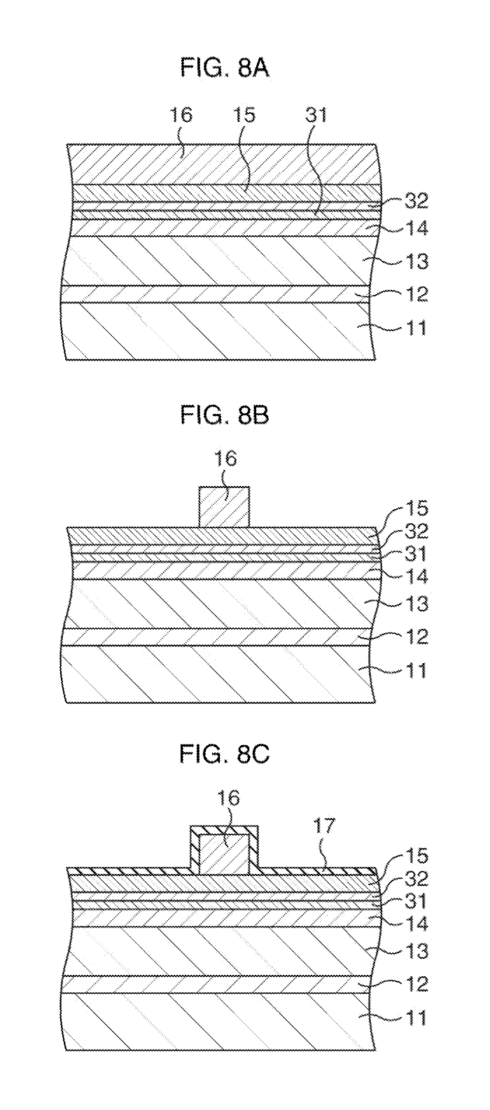

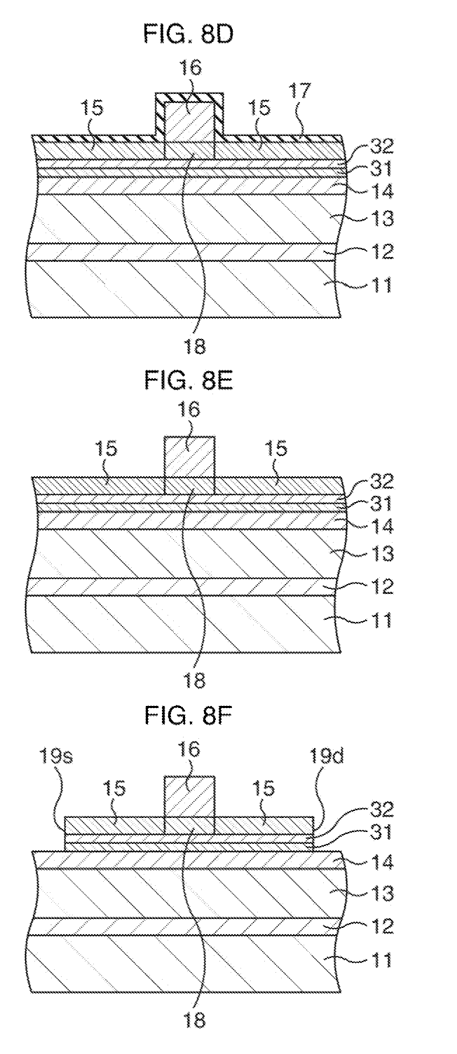

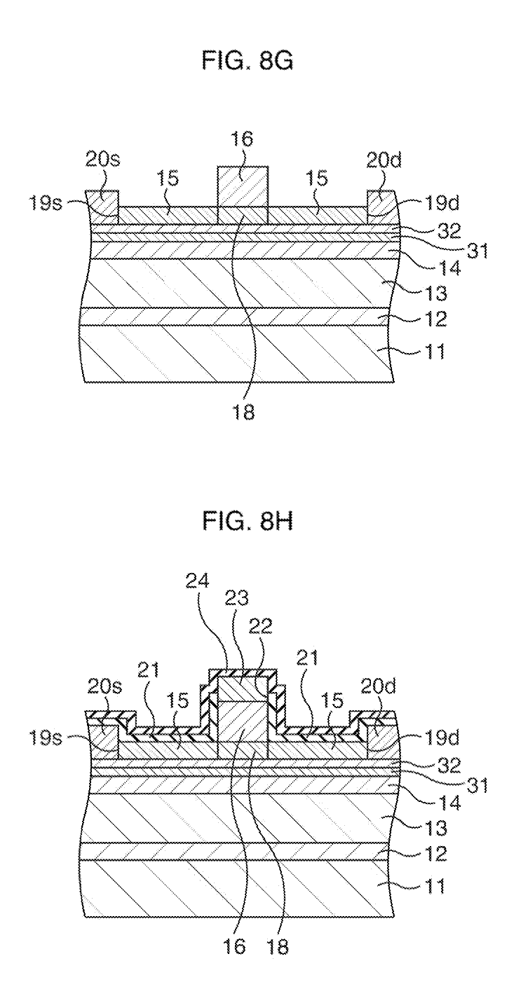

Next, a method of manufacturing the GaN-based HEMT (compound semiconductor device) according to the second embodiment will be explained. FIG. 8A to FIG. 8H are cross sectional views illustrating, in sequence, the method of manufacturing the GaN-based HEMT (compound semiconductor device) according to the second embodiment.

First, the buffer layer 12, the electron transport layer 13, the electron supply layer 14, the n-type compound semiconductor layer 31, the AlN layer 32, the n-type compound semiconductor layer 15 and the p-type compound semiconductor layer 16 are formed over the substrate 11, as illustrated in FIG. 8A. The buffer layer 12, the electron transport layer 13, the electron supply layer 14, the n-type compound semiconductor layer 31, the AlN layer 32, the n-type compound semiconductor layer 15 and the p-type compound semiconductor layer 16 may be formed by a crystal growth method such as an MOVPE, for example, similarly to the first embodiment. Then, the element isolation region which defines the element region is formed in a compound semiconductor stacked structure including the buffer layer 12, the electron transport layer 13, the electron supply layer 14, the n-type compound semiconductor layer 31, the AlN layer 32, the n-type compound semiconductor layer 15 and the p-type compound semiconductor layer 16, similarly to the first embodiment.

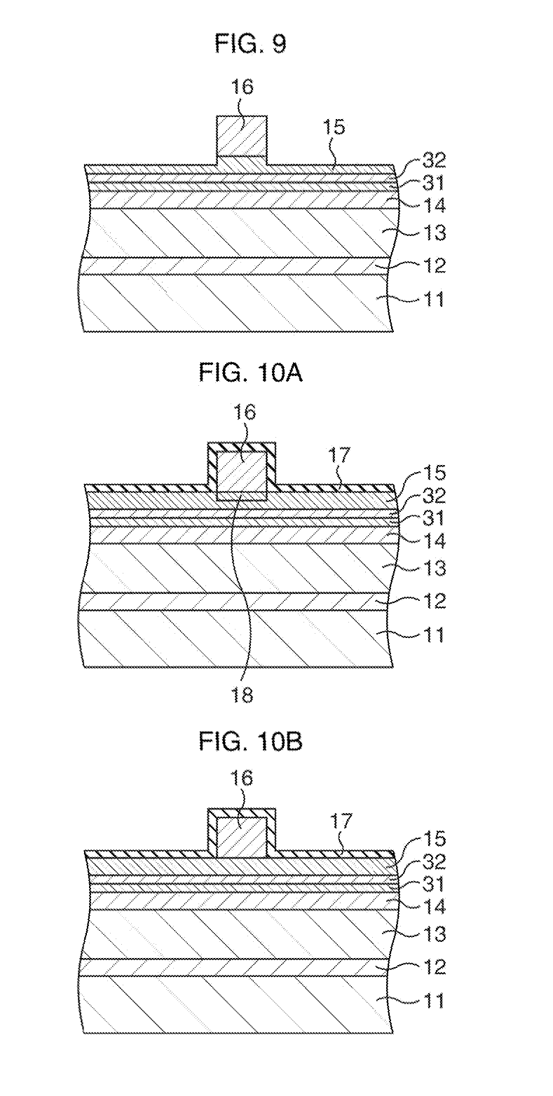

Thereafter, the resist pattern is formed over the p-type compound semiconductor layer 16 so as to selectively cover the region where the p-type compound semiconductor layer 16 is to remain and expose the other region, similarly to the first embodiment. The p-type compound semiconductor layer 16 is dry-etched with the resist pattern used as a mask, as illustrated in FIG. 8B. A chlorine-containing gas, for example, may be used for an etching gas in the dry etching. The dry etching is controlled so as to end at a point in the n-type compound semiconductor layer 15 in order to certainly remove the part of the p-type compound semiconductor layer 16 exposed from the resist pattern. The dry etching is also controlled so as to remain the n-type compound semiconductor layer 15 even at a region where the etching amount is the highest in consideration of variation of the etching rate in plane. Half of the n-type compound semiconductor layer 15, for example, may be etched in the thickness direction, as illustrated in FIG. 9.

Subsequently, the protective film 17 is formed over the n-type compound semiconductor layer 15 so as to cover the p-type compound semiconductor layer 16, as illustrated in FIG. 8C. A silicon nitride film may be formed for the protective film 17, for example.

Then, annealing is performed so as to activate the p-type impurity, for example Mg, in the p-type compound semiconductor layer 16. Moreover, the p-type impurity in the p-type compound semiconductor layer 16 diffuses into the n-type compound semiconductor layer 15 during the annealing, and the p-type region 18 is formed, as illustrated in FIG. 8D.

Thereafter, the protective film 17 is removed, as illustrated in FIG. 8E. The protective film 17 may be removed with hydrofluoric acid, for example.

Subsequently, the recess 19s and the recess 19d are formed in the n-type compound semiconductor layer 15, the AlN layer 32 and the n-type compound semiconductor layer 31 in the element region, as illustrated in FIG. 8F. In forming the recess 19s and the recess 19d, for example, a resist pattern is formed over the n-type compound semiconductor layer 15 and the p-type compound semiconductor layer 16 so as to selectively expose the regions where the recess 19s and the recess 19d are to be formed and cover the other region, and then, dry etching is performed with a chlorine-containing gas using the resist pattern as a mask.

Then, the source electrode 20s is formed in the recess 19s, and the drain electrode 20d is formed in the recess 19d, as illustrated in FIG. 8G. Then, annealing is performed, for example, in a nitrogen atmosphere at approximately 400° C. to 1000° C., for example 600° C. or around, so as to ensure ohmic characteristic of the source electrode 20s and the drain electrode 20d.

Thereafter, the forming of the passivation film 21 and the processes thereafter are performed similarly to the first embodiment, as illustrated in FIG. 8H.

The GaN-based HEMT according to the second embodiment may be thus manufactured.

The p-type compound semiconductor layer 16 may be etched sufficiently with avoiding the electron supply layer 14 being thinned also in the method. Accordingly, the increase of resistance and the decrease of maximum current can be suppressed, while the normally-off operation can be achieved.

Incidentally, similarly to the first embodiment, in some cases, the n-type compound semiconductor layer 15 may remain beneath the p-type region 18, as illustrated in FIG. 10A, and the p-type region 18 may be rarely formed, as illustrated in FIG. 10B, depending on conditions of the activating annealing. Conditions of the activating annealing are not limited to particular ones, and it is preferable that the annealing is performed so as for the p-type impurity in the p-type compound semiconductor layer 16 not to diffuse up to the electron supply layer 14, in short, for the diffusion to stop in the n-type compound semiconductor layer 15.

### Third Embodiment

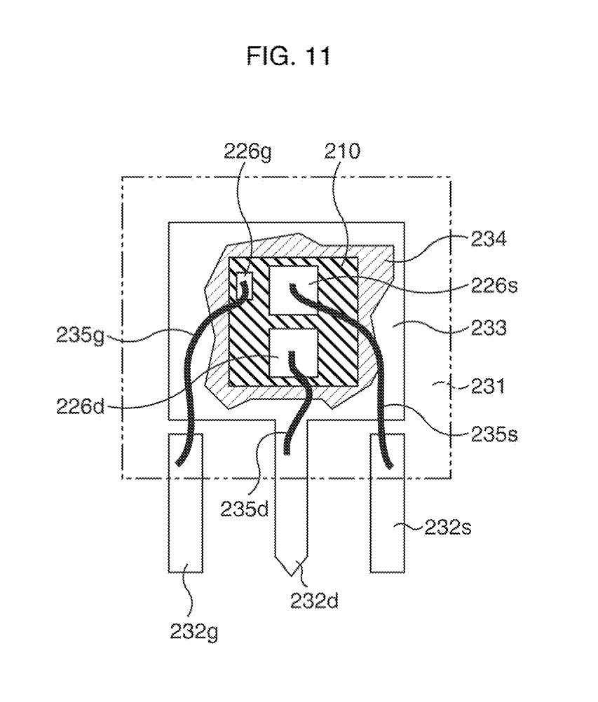

A third embodiment relates to a discrete package of a compound semiconductor device which includes a GaN-based HEMT. FIG. 11 is a drawing illustrating the discrete package according to the third embodiment.

In the third embodiment, as illustrated in FIG. 11, a back surface of a HEMT chip 210 of the compound semiconductor device according to any one of the first to second embodiments is fixed on a land (die pad) 233, using a die attaching agent 234 such as solder. One end of a wire 235d such as an Al wire is bonded to a drain pad 226d, to which the drain electrode 20d is connected, and the other end of the wire 235d is bonded to a drain lead 232d integral with the land 233. One end of a wire 235s such as an Al wire is bonded to a source pad 226s, to which the source electrode 20s is connected, and the other end of the wire 235s is bonded to a source lead 232s separated from the land 233. One end of a wire 235g such as an Al wire is bonded to a gate pad 226g, to which the gate electrode 23 is connected, and the other end of the wire 235g is bonded to a gate lead 232g separated from the land 233. The land 233, the HEMT chip 210 and so forth are packaged with a molding resin 231, so as to project outwards a portion of the gate lead 232g, a portion of the drain lead 232d, and a portion of the source lead 232s. The discrete package may be manufactured by the procedures below, for example. First, the HEMT chip 210 is bonded to the land 233 of a lead frame, using a die attaching agent 234 such as solder. Next, with the wires 235g, 235d and 235s, the gate pad 226g is connected to the gate lead 232g of the lead frame, the drain pad 226d is connected to the drain lead 232d of the lead frame, and the source pad 226s is connected to the source lead 232s of the lead frame, respectively, by wire bonding. Then molding with the molding resin 231 is conducted by a transfer molding process. The lead frame is then cut away.

### Fourth Embodiment

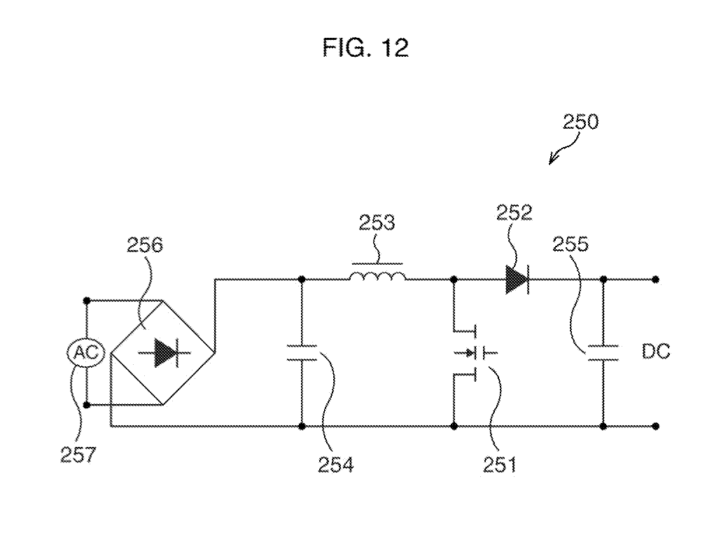

Next, a fourth embodiment will be explained. The fourth embodiment relates to a PFC (power factor correction) circuit equipped with a compound semiconductor device which includes a GaN-based HEMT. FIG. 12 is a wiring diagram illustrating the PFC circuit according to the fourth embodiment.

The PFC circuit 250 includes a switching element (transistor) 251, a diode 252, a choke coil 253, capacitors 254 and 255, a diode bridge 256, and an AC power source (AC) 257. The drain electrode of the switching element 251, the anode terminal of the diode 252, and one terminal of the choke coil 253 are connected with each other. The source electrode of the switching element 251, one terminal of the capacitor 254, and one terminal of the capacitor 255 are connected with each other. The other terminal of the capacitor 254 and the other terminal of the choke coil 253 are connected with each other. The other terminal of the capacitor 255 and the cathode terminal of the diode 252 are connected with each other. A gate driver is connected to the gate electrode of the switching element 251. The AC 257 is connected between both terminals of the capacitor 254 via the diode bridge 256. A DC power source (DC) is connected between both terminals of the capacitor 255. In the embodiment, the compound semiconductor device according to any one of the first to second embodiments is used as the switching element 251.

In the process of manufacturing the PFC circuit 250, for example, the switching element 251 is connected to the diode 252, the choke coil 253 and so forth with solder, for example.

### Fifth Embodiment

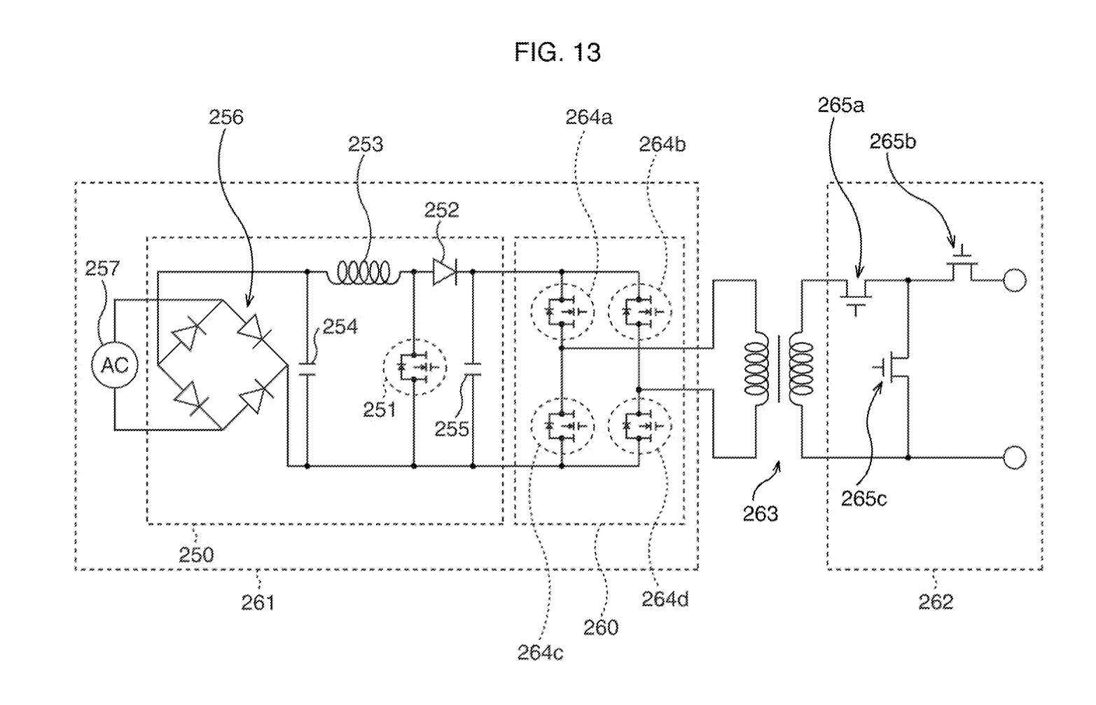

Next, a fifth embodiment will be explained. The fifth embodiment relates to a power supply apparatus equipped with a compound semiconductor device which includes a GaN-based HEMT. FIG. 13 is a wiring diagram illustrating the power supply apparatus according to the fifth embodiment.

The power supply apparatus includes a high-voltage, primary-side circuit 261, a low-voltage, secondary-side circuit 262, and a transformer 263 arranged between the primary-side circuit 261 and the secondary-side circuit 262.

The primary-side circuit 261 includes the PFC circuit 250 according to the fourth embodiment, and an inverter circuit, which may be a full-bridge inverter circuit 260, for example, connected between both terminals of the capacitor 255 in the PFC circuit 250. The full-bridge inverter circuit 260 includes a plurality of (four, in the embodiment) switching elements 264a, 264b, 264c and 264d.

The secondary-side circuit 262 includes a plurality of (three, in the embodiment) switching elements 265a, 265b and 265c.

In the embodiment, the compound semiconductor device according to any one of first to second embodiments is used for the switching element 251 of the PFC circuit 250, and for the switching elements 264a, 264b, 264c and 264d of the full-bridge inverter circuit 260. The PFC circuit 250 and the full-bridge inverter circuit 260 are components of the primary-side circuit 261. On the other hand, a silicon-based general MIS-FET (field effect transistor) is used for the switching elements 265a, 265b and 265c of the secondary-side circuit 262.

### Sixth Embodiment

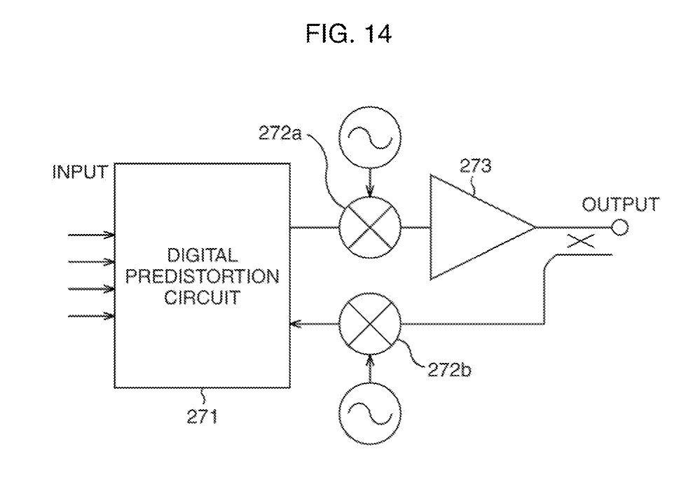

Next, a sixth embodiment will be explained. The sixth embodiment relates to a high-frequency amplifier (high-output amplifier) equipped with a compound semiconductor device which includes a GaN-based HEMT. FIG. 14 is a wiring diagram illustrating the high-frequency amplifier according to the sixth embodiment.

The high-frequency amplifier includes a digital predistortion circuit 271, mixers 272a and 272b, and a power amplifier 273.

The digital predistortion circuit 271 compensates non-linear distortion in input signals. The mixer 272a mixes the input signal having the non-linear distortion already compensated, with an AC signal. The power amplifier 273 includes the compound semiconductor device according to any one of the first to second embodiments, and amplifies the input signal mixed with the AC signal. In the illustrated example of the embodiment, the signal on the output side may be mixed, upon switching, with an AC signal by the mixer 272b, and may be sent back to the digital predistortion circuit 271.

Composition of the compound semiconductor layers used for the compound semiconductor stacked structure is not specifically limited, and GaN, AlN, InN and so forth may be used. Also mixed crystals of them may be used.

Configurations of the gate electrode, the source electrode and the drain electrode are not limited to those in the above-described embodiments. For example, they may be configured by a single layer. The method of forming these electrodes is not limited to the lift-off process. The annealing after the formation of the source electrode and the drain electrode may be omissible, so long as the ohmic characteristic is obtainable. The gate electrode may be annealed.

In the embodiments, the substrate may be a silicon carbide (SiC) substrate, a sapphire substrate, a silicon substrate, a GaN substrate, a GaAs substrate or the like. The substrate may be any of electro-conductive, semi-insulating, and insulating ones. It is preferable to use a Si substrate (one in which the surface has a Miller index of (111) plane, for example), a SiC substrate or a sapphire substrate in view of cost. The thickness and material of each of these layers are not limited to those in the above-described embodiments.

According to the compound semiconductor device and so forth described above, the normally-off operation can be achieved with excellent characteristics, since an appropriate p-type compound semiconductor layer is formed along with an n-type compound semiconductor layer.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising;
a substrate;
an electron transport layer formed over the substrate;
an electron supply layer formed over the electron transport layer;
a source electrode and a drain electrode formed over the electron supply layer;
a gate electrode formed over the electron supply layer between the source electrode and the drain electrode;
a p-type compound semiconductor layer formed between the electron supply layer and the gate electrode; and
a compound semiconductor layer containing an n-type impurity formed between the electron supply layer and the p-type compound semiconductor layer.

2. The compound semiconductor device according to claim 1, wherein the compound semiconductor layer containing an n-type impurity further contains a p-type impurity.

3. The compound semiconductor device according to claim 1, wherein the compound semiconductor layer containing an n-type impurity is a GaN layer.

4. The compound semiconductor device according to claim 1, wherein the compound semiconductor layer containing an n-type impurity extends up to the source electrode and the drain electrode.

5. The compound semiconductor device according to claim 1, wherein the p-type compound semiconductor layer is an AlₓGa₁₋ₓN layer (0≦x<1).

6. The compound semiconductor device according to claim 1, further comprising:
an AlN layer formed between the electron supply layer and the compound semiconductor layer containing an n-type impurity; and
an n-type compound semiconductor layer formed between the electron supply layer and the AlN layer.

7. The compound semiconductor device according to claim 6, wherein the n-type compound semiconductor layer is a GaN layer.

8. The compound semiconductor device according to claim 1, wherein each of the electron transport layer and the electron supply layer contains a GaN-based material.

9. A power supply apparatus, comprising
a compound semiconductor device, which comprises:
a substrate;
an electron transport layer formed over the substrate;
an electron supply layer formed over the electron transport layer;
a source electrode and a drain electrode formed over the electron supply layer;
a gate electrode formed over the electron supply layer between the source electrode and the drain electrode;
a p-type compound semiconductor layer formed between the electron supply layer and the gate electrode; and
a compound semiconductor layer containing an n-type impurity formed between the electron supply layer and the p-type compound semiconductor layer.

10. An amplifier, comprising
a compound semiconductor device, which comprises:
a substrate;
an electron transport layer formed over the substrate;
an electron supply layer formed over the electron transport layer;
a source electrode and a drain electrode formed over the electron supply layer;
a gate electrode formed over the electron supply layer between the source electrode and the drain electrode;
a p-type compound semiconductor layer formed between the electron supply layer and the gate electrode; and
a compound semiconductor layer containing an n-type impurity formed between the electron supply layer and the p-type compound semiconductor layer.

11. A method of manufacturing a compound semiconductor device, comprising:
forming an electron transport layer over a substrate;
forming an electron supply layer over the electron transport layer;
forming a compound semiconductor layer containing an n-type impurity over the electron supply layer;
forming a p-type compound semiconductor layer over the compound semiconductor layer containing an n-type impurity;
etching the p-type compound semiconductor layer so as to remain a part of the p-type compound semiconductor layer;
annealing so as to activate a p-type impurity in the p-type compound semiconductor layer;
forming a source electrode and a drain electrode over the electron supply layer so that the remaining part of the p-type compound semiconductor layer is between the source electrode and the drain electrode; and
forming a gate electrode over the remaining part of the p-type compound semiconductor layer.

12. The method of manufacturing a compound semiconductor device according to claim 11, wherein the p-type impurity in the p-type compound semiconductor layer diffuses into the compound semiconductor layer containing an n-type impurity during the annealing.

13. The method of manufacturing a compound semiconductor device according to claim 11, wherein the compound semiconductor layer containing an n-type impurity is a GaN layer.

14. The method of manufacturing a compound semiconductor device according to claim 11, wherein the p-type compound semiconductor layer is an AlₓGa₁₋ₓN layer (0≦x<1).

15. The method of manufacturing a compound semiconductor device according to claim 11, further comprising, before the forming the compound semiconductor layer containing an n-type impurity:
forming an n-type compound semiconductor layer over the electron supply layer; and
forming an AlN layer over the n-type compound semiconductor layer.

16. The method of manufacturing a compound semiconductor device according to claim 15, wherein the n-type compound semiconductor layer is a GaN layer.

17. The method of manufacturing a compound semiconductor device according to claim 11, wherein each of the electron transport layer and the electron supply layer contains a GaN-based material.

18. The method of manufacturing a compound semiconductor device according to claim 11, wherein the annealing is performed after the etching.
